(19) United States
(12) Patent Application Publication
(10) Pub. No.: US 2026/0109085 A1
(43) Pub. Date: Apr. 23, 2026

(54) MOLD RELEASE AGENT FOR POLYURETHANE ARTICLES

(71) Applicant: Evonik Operations GmbH, Essen (DE)

(72) Inventors: Rene Kerp, Bochum (DE); Alfred Vuin, Wiesbaden (DE); Florian Gaber, Muelheim an der Ruhr (DE); Michael Krebs, Monheim (DE)

(73) Assignee: Evonik Operations GmbH, Essen (DE)

(21) Appl. No.: 19/477,182

(22) PCT Filed: Apr. 17, 2024
(86) PCT No.: PCT/EP2024/060324

§ 371 Date: Oct. 21, 2025

(30) Foreign Application Priority Data
Apr. 27, 2023 (EP) 23170294.5

(51) Int. Cl. B29C 33/60; B29C 35/08; B29K 75/00; G03F 7/031

(52) U.S. Cl. CPC B29C 33/60; G03F 7/031; B29C 2035/0827; B29C 2035/0833; B29K 2075/00

(57) ABSTRACT

The present invention is related to an aqueous mold release agent for the production of polyurethane articles, particularly molded polyurethane foam articles, comprising an unsaturated polymer and a Norrish-type 1 and or a Norrish-type 2 photoinitiator, characterized in that the unsaturated polymer comprises a polybutadiene, a polyisoprene, a copolymer of butadiene and isoprene, or a combination thereof. The present invention is further directed to a process of producing a molded polyurethane article, comprising applying said aqueous agent to a mold, and to the use said aqueous mold release agent for the production of molded polyurethane articles

### TECHNICAL FIELD

The present invention is related to an aqueous mold release agent for the production of polyurethane articles, particularly molded polyurethane foam articles. The aqueous agent comprises an unsaturated polymer and a Norrish type 1 or a Norrish type 2 photoinitiator. The present invention is further directed to a process of producing a molded polyurethane article, comprising applying said aqueous agent to a mold and, after removing the article from the mold, a step of irradiating at least a part of the surface of the article with UV radiation. The present invention is also directed to the use said aqueous mold release agent for the production of molded polyurethane articles.

### TECHNICAL BACKGROUND

Polyurethanes are often used main components for cushions, for example in the automotive industry. For this application, a small amount of water is added to the reaction mixture comprising polyol and isocyanate monomers, resulting in the formation of carbon dioxide and foaming of the resulting polymer. The mixture is injected into a mold to form the desired body to be used as the filler material. Polyurethanes are also known in the art to exhibit strong adhesion towards other materials, thus leading to polyurethanes being used in a broad range of adhesive compositions. However, this property of polyurethanes is highly disadvantageous when preparing molded polyurethane articles, as the resulting polyurethane article adheres to the mold, making it almost impossible to remove the article without causing damage to the molded product.

Therefore, the use of a mold release agent is necessary. The release agent is applied to the mold prior to forming the article, usually by spraying the agent directly into the mold. Once the polyurethane article has been molded, the polyurethane adheres to the release agent, while the release agent exhibits very low adhesion to the mold, allowing for an easy removal of the article from the mold without causing damage to it.

Such release agents can comprise waxes, soaps, oils or polymers as the active ingredient responsible for lowering the adhesion to the mold. In the past, solvent-based release agents, i.e., release agents comprising a volatile organic solvent as the carrier, were commonly used. These solvent-based agents, particularly when based on waxes as release active substances, have the advantage that, once the solvent is evaporated, a dry surface of the molded article is received, which is ready for further processing. Depending of the intended use of the molded article, further processing can comprise for example applying adhesives, lacquers or coatings. However, the use of volatile organic solvents has become unwanted due to their environmental impact and the costs of removing solvent vapors from exhaust air to meet emission limits.

To overcome this problem, water-based mold release agents were developed. Such agents use water as the carrier and low molecular weight polybutadiene or polyisoprene as the active ingredient, as disclosed for example in EP 0 320 833 A2. Other water-based release agents utilize oils, waxes or fatty esters as active release agents, as disclosed in EP 0 460 783 A1. Water-based release agents have the advantage that they produce highly reduced emissions. However, while water-based release agents using waxes as active ingredients tend to adhere to the mold, while polybutadiene or polyisoprene as the active release ingredient leave a smeary wet surface of the molded article, which is very useful for removing the article from the mold, but undesired for further processing of the article, as for example coatings, adhesives or lacquers only poorly adhere to said smeary wet surface. The respective effects of different combinations of carriers and release active ingredients is shown in Table 1 below:

TABLE 1
influence of carrier and release active ingredient on release
effect and surface properties of molded polyurethane articles

| | Active | Release | Surface |
|---|---|---|---|
| Carrier | ingredient | effect | properties |
| Org. solvent | Wax | Good | Dry |
| Org. solvent | Oil | Good | Smeary |
| Org. solvent | Unsaturated polymers | Good | Smeary |
| Water | Wax | Poor | Dry |
| Water | Oil | Good | Smeary, tacky |
| Water | Unsaturated polymers | Good | Smeary |

US 2005/0239935 A1 discloses a mold release agent comprising an aqueous carrier, an unsaturated polymer and further a Norrish type 1 photoinitiator and/or a Norrish type 2 photoinitiator. Said mold release agent may be included in the radiation curable composition to facilitate the release of the polymer shim from the master mold and prolong the life of the master mold.

WO 01/98817 A2 discloses radiation-curable carrier systems which are suitable for forming an ink composition containing one or more radiation-curable oligomers or monomers having at least one functional group capable of oligomerization when exposed to actinic radiation. The photoinitiators used in this ink composition are preferably free-radical photoinitiators such Norrish type I and Norrish type 2 photoinitiators.

There is consequently a need for improved mold release agents, which combine the advantages of solvent-based and water-based mold release agents without producing emissions of volatile organic solvents.

### SUMMARY OF THE INVENTION

It was therefore an object of the present invention to provide an improved water-based mold release agent for polyurethane-based articles, which enables easy removal of the article from the mold, but which can also be easily cured to provide a surface ready for further processing of the article.

It has been found that, when adding a Norrish type 1 or Norrish type 2 photoinitiator to a water-based mold release agent, the surface of the resulting molded polyurethane article can be irradiated with actinic radiation to initiate a curing process and consequently to change the properties of the agent adhering to the surface of the polyurethane article from smeary wet to at least waxy, or even solid and dry, rendering the surface ready for further processing.

The present invention is therefore directed to a mold release agent for the production of molded polyurethane articles comprising an aqueous carrier, an unsaturated polymer and further a Norrish-type 1 and/or a Norrish-type 2 photoinitiator, such as an acetophenone type 1 photoinitiator, a benzophenone-based type 2 photoinitiator or a phosphine oxide photoinitiator, characterized in that the unsaturated polymer comprises a polybutadiene, a polyisoprene, a copolymer of butadiene and isoprene, or a combination thereof.

The present invention is further directed to a process of producing a molded polyurethane article, characterized in that the process comprises applying said aqueous mold release agent to a mold and, after removing the article from the mold, a step of irradiating at least a part of the surface of the article with actinic radiation having a wavelength of 100 nm to 800 nm.

Furthermore, the present invention is directed to the use of said aqueous mold release agent for the production of molded polyurethane articles.

### DETAILED DESCRIPTION

Any numerical value disclosed herein inherently contains certain errors necessarily resulting from the standard variation found in their respective testing measurements.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

The term “curing” refers to the process by which a composition or an agent solidifies or hardens by undergoing a chemical reaction either with itself or with a crosslinking agent. Correspondingly, the term “cured” refers to the state of a composition or an agent having changed from liquid or flowable to at least highly viscous and tacky, or even solid and dry.

The term “polymer” refers to both homo- and copolymers, while copolymers may comprise random, block and graft copolymers.

The Norrish-type 1 or Norrish-type 2 photoinitiator (photoinitiator) in the mold releasing agent according to the present invention is an initiator which does not require a co-initiator in order to produce free radicals if irradiated with actinic radiation corresponding to its absorption maximum.

Upon irradiation with actinic radiation having a wavelength close to its absorption maximum, a photoinitiator will undergo a homolytic α-cleavage, resulting in several highly reactive radicals. A skilled person will acknowledge that photoinitiators comprise monomeric- or polymeric derivatives of acetophenone, acylphosphine oxides, benzoin ethers, benzophenone and thioxanthones, including the respective unsubstituted compounds, i.e. compounds comprising an α-phenyl ketone substructure. Examples of such derivatives may comprise acetophenone, anisoin, benzoin, benzophenone, benzoin ethyl ether, benzoin isobutyl ether, benzoin methyl ether, 3,3′,4,4′-Benzophenonetetracarboxylic dianhydride, 4-Benzoylbiphenyl, 2-Benzyl-2-(dimethylamino)-4′-morpholinobutyrophenone, 4,4′-Bis(diethylamino)benzophenone, 4,4′-Bis(dimethylamino)benzophenone, 2,2-Diethoxyacetophenone, 2,2-dimethyl-2-hydroxyacetophenone, 2,2-dimethyl-2-aminoacetophenone, 2,2-diethyl-2-hydroxyacetophenone, 2,2-diethyl-2-aminoacetophenone, 2,2-diethoxy-2-hydroxyacetophenone, 2,2-diethoxy-2-aminoacetophenone, 4,4′-Dihydroxybenzophenone, 2,2-Dimethoxy-2-phenylacetophenone, 4-(Dimethylamino)benzophenone, 2,5-Dimethylbenzophenone, 3,4-Dimethylbenzophenone, 2-Hydroxy-2-methyl-4′-alkylpropiophenone, 4′-Ethoxyacetophenone, 3-Hydroxyacetophenone, 4′-Hydroxyacetophenone, 3-Hydroxybenzophenone, 4-Hydroxybenzophenone, 1-Hydroxycyclohexyl phenyl ketone, 2-Hydroxy-2-methylpropiophenone, 2-Methylbenzophenone, 3-Methylbenzophenone, Methybenzoylformate, 2-Methyl-4′-(methylthio)-2-morpholinopropio-phenone and 4′-Phenoxyacetophenone. A selection of photoinitiators is described in “A Compilation of Photoinitiators Commercially available for UV today” (K. Dietliker, SITA Technology Ltd, London 2002).

Examples for a photoinitiators that may be used in the present invention are α-hydroxyacetophenones, α-aminoacetophenones, acylphosphine oxides and benzophenones, more preferably α-hydroxyacetophenones, such as a photoinitiator that is selected from hydroxyacetophenones, e.g. an α-hydroxyacetophenone having the following formula

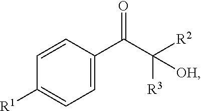

wherein R¹ is a linear or branched C₈ to C₂₀ alkyl, R² and R³ are independently C₁ to C₃ alkyl or ethoxy. Most preferred, R¹ is a linear or branched C₁₀ to C₁₃ alkyl and/or R² and R³ are methyl.

The acetophenone- or benzophenone-based type 1 photoinitiator may be present in the inventive mol release agent in an amount of 0.01 wt.-% to 20 wt.-%, preferably 1 wt.-% to 10 wt.-%, based on the total weight of the unsaturated polymer.

The mold release agent further comprises an unsaturated polymer. The polymer backbone therefore comprises at least one non-conjugated C—C double bond per repeating unit. Thus, the polymer comprises a polybutadiene, a polyisoprene, a copolymer of butadiene and isoprene, or a combination thereof. Due to the above-mentioned strong adhesive properties of polyurethanes, the unsaturated polymer ideally does not comprise a copolymer of polyurethane with polybutadiene and/or polyisoprene. The polymer may be solid, liquid, or flowable, however, liquid and/or flowable polymers are preferred. It is consequently preferred that the polymer has a molecular weight of at least 500 g/mol, more preferred 1.000 g/mol to 10.000 g/mol, even more preferred 1.500 g/mol to 7.500 g/mol, most preferred 2.000 g/mol to 5.000 g/mol.

The unsaturated polymer may be present in the inventive mold release agent in an amount of 2 wt.-% to 50 wt.-%, preferably 7 wt.-% to 20 wt.-%, more preferred 8 wt.-% to 15 wt.-%, most preferred 9 wt.-% to 12 wt.-%, based on the total weight of the mold release agent. Although the inventive agent may comprise other polymers than the above-defined unsaturated polymer, it is preferred that the agent comprises no more than one polymer in addition to the unsaturated polymer.

The inventive mold release agent comprises an aqueous carrier. It may therefore comprise at least 30 wt-%, preferably at least 45 wt.-%, more preferably at least 60 wt.-%, most preferred at least 70 wt.-%, water. The inventive agent may for example comprise from 30 wt.-% to 80 wt.-% water. The inventive agent may also be substantially free of organic solvents, such as mineral oils, long-chained (more than C₅) alkanes, halogenated alkanes, short chained alcohols including polyols, liquid aryl compounds, ethers, esters, liquid sulfoxides, or liquid lactams. Substantially free in this context may mean that, despite having taken efforts to exclude such solvents from the inventive agent, such solvents may be present in the inventive agent in an amount of up to 5 wt.-%, preferably up to 2.5 wt.-%, more preferably up to 1 wt.-%, most preferred up to 0.1 wt.-%, based on the total weight of the mold release agent.

The mold release agent according to the present invention may further comprise any further ingredients commonly used in mold release agents. Such ingredients may comprise thickeners, foam stabilizers, such as polysiloxane-polyether-copolymers, emulsifiers, biocides, quaternary ammonium compounds, catalysts, in particular catalysts for the formation of polyurethane, and dispersion aids. The before-mentioned catalysts may for example comprise tin salts, such as tin salts of organic acids, organotin compounds, such as dimethyl tin dilaurate or dibutyl tin dilaurate, bismuth(III)-compounds, such as bismuth(III) salts of organic and inorganic acids and bismuth(III) complexes, and amine catalysts. The before-mentioned compounds may be present in the inventive mold release agent in a total amount of up to 15 wt.-%, preferably up to 10 wt.-%, based on the total weight of the mold release agent.

Suitable emulsifiers may comprise ionic and nonionic surfactants. Ionic surfactants may for example comprise (ethoxylated) fatty amines, which are protonated with acetic acid, preferably (ethoxylated) fatty amines comprising 16 to 18 carbon atoms. Nonionic surfactants may comprise ethoxylated and/or propoxylated fatty alcohols, or (ethoxylated) fatty amines. Among these emulsifiers, narrow range ethoxylated fatty alcohols and fatty amines are preferred. Particularly preferred ethoxylated fatty alcohols comprise fatty alcohols with 4 to 10 EO, more preferred 6 to 10 EO, such as fatty alcohols with 8 EO. If present, emulsifiers may be present in the mold release agent according to the invention in a total amount of 2 wt.-% to 6 wt.-%, preferably 3 wt.-% to 5 wt.-%, based on the total weight of the mold release agent.

The present invention further refers to a process of producing a molded polyurethane article. The process comprises as obligate steps (i) a step of applying the aqueous mold release agent as described above to a mold and (ii), after removing the article from the mold, a step of irradiating at least a part of the surface of the article with actinic radiation having a wavelength of 100 nm to 800 nm.

The aqueous mold release agent according to the invention may particularly be applied to the open mold by spraying, brush application, or application using a wipe impregnated with the inventive agent. The spraying may be conducted by using any techniques known in the art, for example using an airless spray gun.

The article may be formed by any molding techniques and using any compositions useful for forming polyurethane articles by molding processes known in the art, in particular compositions comprising at least one diol and at least one diisocyanate.

Before, or immediately after spraying, the mold may be heated to 40° C. to 80° C. to evaporate at least parts of the aqueous carrier. Then, a reactive composition comprising polyols, polyisocyanates and further optional additives, like catalysts, foam stabilizers and propellants, may be injected into the mold. After the polyurethane composition is cured, the mold may be opened and the formed polyurethane article may be removed from the mold.

As part of the inventive process, at least a part of the article is then irradiated with actinic radiation having a wavelength of 100 nm to 800 nm in order to cure the mold release agent present on the surface of the molded article. The source of the actinic radiation may be selected depending on the required emission maximum, which depends on the absorption maximum of the used photoinitiator. Suitable UV sources are known in the art and include mercury vapor lamps, gas discharge lamps, as well as ultraviolet LEDs and lasers. Preferably, the actinic radiation may have a wavelength of 100 nm to 450 nm, more preferably 200 to 400 nm. The radiation source may have a power output of 20 to 2000 W, preferably 40 to 400 W.

The process of irradiation can be conducted from 20° C. to 100° C., preferably from 20° C. to 60° C. The at least one part of the surface of the molded article may be irradiated for 1 seconds to 300 seconds.

Only predetermined parts of the article's surface of the whole surface may be subjected to irradiation. This depends on the desired surface characteristics of the molded article.

The present invention further refers to the use of the before-mentioned mold release agent in the production of molded polyurethane articles. Such articles may preferably be molded polyurethane foam articles.

These articles, after the curing step of the inventive process, may be upholstered with materials such as textiles, fabrics, fleece, leather or other materials for upholstering automotive seats, furniture or mattresses.

### EXAMPLES

Several mold release agents were prepared having the compositions as set forth in Table 2 below:

TABLE 2
Exemplified composition of inventive release agents

| Ingredient | Amount (wt.-%) |
|---|---|
| Polybutadiene (2000 g/mol to 5000 g/mol) | 10 |
| Photoinitiator (1-Propane, | Varying amounts |
| 2-hydroxy-2-methyl, -1-(4-C₁₀₋₁₃- | from 0.1 to 1.5 |
| alkylphenyl) derivs.) | |
| Fatty alcohol ethoxylate C₁₄-C₂₀ | 2.5 |
| Antioxidant | 0.1 |
| DBTDL | 0.3 |
| Isoparaffinic solvent C₁₀-C₁₃ | 0-5 |
| Water | Remainder |

Before foam production, a mold was treated with a water-based inventive agent as described above.

The polyurethane foams were produced as so-called molded foams in the laboratory according to the two foam formulations. The foams were produced according to the following specifications at 22° C. and 762 mm Hg air pressure: A heated aluminum mold measuring 40 cm×40 cm×10 cm was used to produce the foams. The molding temperature was between 60-70° C.

The testing was carried out using two foam different systems:
Methylenediphenylisocyanate-based polyurethane system: Polyol: Elastoflex W5515/146 (BASF); isocyanate: Methylenediphenylisocyanate,
Toluenediisocyanate-based polyurethane system: Polyol: see Table 3; isocyanate: DESMODUR T80 (2,4- and 2,6-Toluenediisocyanate, Covestro)

TABLE 3
Composition of the polyol part of
the TDI-based polyurethane system:

| Component | PPHP |
|---|---|
| Hyperlite ®1629 | 70 |
| (Polyetherpolyol) | |
| Hyperlite ®1650 | 30 |
| (Polyetherpolyol) | |
| Diethanolamine (85%) | 0.94 |
| Water | 2.86 |
| DABCO ®NE300 | 0.15 |
| (catalyst) | |
| DABCO ®NE1600 | 0.50 |
| (catalyst) | |
| Tegostab ®B8761 LF2 | 0.70 |
| (surfactant) | |
| Glycerol | 0.60 |

Demolding time for both systems: 5 min

It was found that each article was easily removable from the mold without incurring damage to the article. It was further observed that each molded article had a smeary wet surface after removing it from the mold.

After the release, a foam pattern 17 cm×5 cm×1 cm (length, width, height) was irradiated for 1-300 sec with a UV-Lamp with 100-400 nm and having a power output of 40 to 120 W, during which a solidification of the material on the surface of the molded articles was observed.

Each molded article was then subjected to a peel strength test (method A) and an axial detachment test (method B) using a FT 7999 double coated nonwoven adhesive foil (Avery Dennison). Before testing, the test specimen were conditioned at room temperature for 24 hours. The test conditions were as follows:

### Method A:

Foam specimen minimum size 200×50×10 mm, adhesive tape 200×50 mm. The test must be performed on three specimens after 10 minutes from the specimen's preparation and on other three specimens after 72 h form the specimen's preparation.

The protective liner from the adhesive band specimen was removed, the band was overlapped and aligned with the foam pad, and a pressure roller (5 kg) was rolled over the specimen four times, to ensure reciprocal bonding. The foam was fixed in an upper clamp, while the tape was fixed in a lower clamp. The lower clamp was pulled at 100 mm/min with a pre-force of 0.1 N at an angle of 180 degrees until adhesive failure. Results are given as arithmetic average of both systems indicated above, with six measurements per foam system.

### Method B:

Foam specimen minimum size 100×50×25 mm, adhesive tape 100×25 mm.

The adhesive tape was attached to the foam specimen with an overlap of 50 mm and the foam was fixed in an upper clamp, while the tape was fixed in a lower clamp (25 mm each). Starting distance between clamps was 100 mm. The dynamometer was started at a speed of 100 mm/min until adhesive failure. Results are given as arithmetic average of both systems indicated above, with three measurements per foam system.

Results are given in Table 3 below. Foam A is a foam as prepared according to the inventive example after irradiation. Foam B is a foam as prepared according to the inventive example before irradiation. Foam C is a foam as prepared using a conventional solvent-based release agent, which was not irradiated.

TABLE 3
Test results

| | Method A: | | Method B: |
|---|---|---|---|
| | Maximum | Method A: | Maximum |
| Foam | force | Adhesion | detachment load |
| A | 4.98N | 0.298N/cm | 60.84N |
| B | 0.24N | 0.014N/cm | 15.05N |
| C | 3.82N | — | 38.03N |

These results show that the mold release agent according to the present invention allows easy removal of the molded article from the mold without risking any damage to the article. Additionally, the article can be easily cured, rendering the surface of the molded article ready for further processing, such as the application of an adhesive, a coating or a lacquer.

1. An aqueous mold release agent for the production of molded polyurethane articles, the aqueous mold release agent comprising:
an aqueous carrier,
an unsaturated polymer, and
further a Norrish-type 1 photoinitiator and/or a Norrish type 2 photoinitiator, wherein the unsaturated polymer comprises a polybutadiene, a polyisoprene, a copolymer of butadiene and isoprene, or a combination thereof.

2. The aqueous mold release agent according to claim 1, wherein a backbone of the unsaturated polymer comprises at least one non-conjugated C—C double bond per repeating unit.

3. The aqueous mold release agent according to claim 1, wherein the unsaturated polymer is present in an amount of 2 wt.-% to 50 wt.-%, based on a total weight of the aqueous mold release agent.

4. The aqueous mold release agent according to claim 1, wherein the unsaturated polymer has a molecular weight of at least 500 g/mol.

5. The aqueous mold release agent according to claim 1, comprising a Norrish type 1 photoinitiator.

6. The aqueous mold release agent according to claim 5, wherein the Norrish-type 1 photoinitiator is an α-hydroxyacetophenone-based Norrish-type 1 photoinitiator.

7. The aqueous mold release agent according to claim 1, wherein the Norrish-type 1 photoinitiator and/or the Norrish-type 2 photoinitiator is present in an amount of 0.01 wt.-% to 20 wt.-%, based on a total weight of the unsaturated polymer.

8. A process of producing a molded polyurethane article, the process comprising:
applying the aqueous mold release agent according to claim 1 to a mold and,
after removing the molded polyurethane article from the mold, irradiating at least a part of a surface of the molded polyurethane article with actinic radiation having a wavelength of 100 nm to 800 nm.

9. The process according to claim 8, wherein the at least part of the surface of the molded polyurethane article is irradiated for 1 seconds to 300 seconds.

10. The process according to claim 8, wherein a source of actinic radiation has an output power of 20 W to 2000 W.

11. The process according to claim 9, wherein the actinic radiation has a wavelength of 100 nm to 450 nm.

12. (canceled)

13. (canceled)
